(19) United States
(12) Patent Application Publication
(10) Pub. No.: US 2005/0093096 A1
(43) Pub. Date: May 5, 2005

(54) Bipolar transistor for avoiding thermal runaway

(76) Inventors: Kazuhiko Honjo, Tokyo (JP); Kazuo Uchida, Tokyo (JP); Shuichi Kato, Kanagawa (JP); Hiroshi Morisaki, Chiba (JP); Shinji Nozaki, Kanagawa (JP); Takahisa Ichinohe, Tokyo (JP)

Correspondence Address: CARRIER BLACKMAN AND ASSOCIATES, 24101 NOVI ROAD, SUITE 100, NOVI, MI, 48375, US

(21) Appl. No.: 10/504,209

(22) PCT Filed: Aug. 1, 2003
(86) PCT No.: PCT/JP03/09778

(30) Foreign Application Priority Data
Aug. 6, 2002 (JP) 2002-229132

(51) Int. Cl. H01L 27/082

(52) U.S. Cl. 257/567; 257/198

(57) ABSTRACT

A bipolar transistor is composed of a collector region, a base region connected to the collector region, an emitter region connected to the base region, an emitter electrode, a base electrode, and at lease one of first and second resistive layers of granular metal-dielectric material. The first resistive layer is disposed between the emitter region and the emitter electrode, and the second resistive layer is disposed between the base region and the base electrode. The resistivity of granular metal-dielectric material is widely adjustable by a volume ratio of metal granules to a dialectic matrix. This allows the resistive layers to have a sufficiently large perpendicular resistance to avoid thermal runaway with a reduced thickness.

### TECHNICAL FIELD

The present invention is related, in general, to bipolar transistors, and more particularly, to bipolar transistors within which ballast resistors are embedded to avoid thermal runaway.

### BACKGROUND ART

Increase in junction temperature of bipolar transistors often causes thermal runaway. Increased junction temperature increases the emitter and base currents because of a negative thermal coefficient of resistivity of semiconductor. Increased emitter and base currents cause a progressive increase in the junction temperature resulting from positive feedback. This often results in thermal runaway and breakdown of the bipolar transistor.

Thermal runaway may be one of serious problems in developing multi-finger HBTs (heterojunction bipolar transistor). Chang-Woo Kim et al. depict a thermal behavior of multi-finger HBTs in a document entitled “Thermal Behavior Depending on Emitter Finger and Substrate Configurations in Power Heterojunction Bipolar Transistors”, IEEE Transactions on Electron Devices, vol. 45, No. 6, June, 1998. A multi-finger HBT includes an array of HBTs arranged in rows and columns, highly integrated within a semiconductor substrate. The collectors, the emitters, and the bases of the HBTs are respectively connected to each other to allow the multi-finger HBT to function as a single bipolar transistor. Although the multi-finger HBT advantageously has a large output current, multi-finger HBTs often suffer from thermal runaway because of their large output current and poor cooling efficiency caused by their high integration density. Multi-finger HBTs must be carefully designed to avoid thermal runaway.

Connecting ballast resistors to emitters and/or bases of bipolar transistors is an effective technique to avoid thermal runaway. A bipolar transistor circuit including bipolar transistors and ballast resistors connected thereto is disclosed in a document entitled “A Study on Ballasting Resistor Design for Uniform Temperature Distribution in Multi-finger HBTs”, Suzuki et al., p. 68, proceedings of 2002 General Conference of the Institute of Electronics, Information, and Communication Engineers. The ballast resistors achieve negative feed back of the emitter currents and the base currents, and effectively avoid thermal runaway.

J. K. Twynam et al. disclose an HBT in “Thermal stabilization of AlGaAs/GaAs power HBT's using n-AlGaAs emitter ballast resistors with high thermal coefficient of resistance”, International Journal of Solid-State Electronics, Vol. 38, No. 9, pp. 1657-1661, September, 1995, an emitter of which includes an n-AlGaAs layer used as a ballast resistor. The n-AlGaAs ballast resistor layer effectively reduces the necessary size for integrating the transistor and the ballast resistor. However, the thickness of the n-AlGaAs ballast resistor layer is inevitably increased to provide sufficient resistance to avoid thermal runaway. For example, the document discloses that the n-AlGaAs ballast resistor layer has a thickness of 370 nm. This thickness is not commercially acceptable.

### DISCLOSURE OF INVENTION

In summary, the present invention addresses an improvement in bipolar transistors within which ballast resistors are embedded.

In detail, one object of the present invention is to provide a bipolar transistor with a ballast resistor layer of a reduced thickness.

Another object of the present invention is to provide a bipolar transistor with a ballast resistor layer for improving RF characteristics.

In an aspect of the present invention, a bipolar transistor is composed of a collector region, a base region connected to the collector region, an emitter region connected to the base region, an emitter electrode, a base electrode, and at lease one of first and second resistive layers of granular metal-dielectric material. The first resistive layer is disposed between the emitter region and the emitter electrode, and the second resistive layer is disposed between the base region and the base electrode. The resistivity of granular metal-dielectric material is widely adjustable by a volume ratio of metal granules to a dialectic matrix. This allows the resistive layers to have a sufficiently large perpendicular resistance to avoid thermal runaway with a reduced thickness.

In the event that the bipolar transistor includes the first resistive layer, the bipolar transistor preferably includes an electrode film disposed between the first resistive layer and the emitter region so that the electrode film and the resistive layer form an ohmic contact.

Correspondingly, the bipolar transistor preferably includes an electrode film disposed between the second resistive layer and the base region SO that the electrode film and the resistive layer form an ohmic contact when the bipolar transistor includes the second resistive layer between the base electrode and the base region.

The dielectric matrix comprised in the resistive layer is preferably formed of high-k material having a relative dielectric constant equal to or more than 10, more preferably equal to or more than 100. The dielectric matrix may consist of perovskite oxides, tantalum oxide, or hafnium oxide.

In order to improve RF characteristics of the bipolar transistor, such as a RF gain, it is advantageous that a temperature coefficient of resistivity of the resistive layer is positive.

A band gap of the emitter region is preferably larger than that of the base region.

In another aspect of the present invention, a multi-finger bipolar transistor is composed of a plurality of bipolar transistors fabricated within a substrate. Each of the plurality of bipolar transistors includes a collector region, a base region connected to the collector region, an emitter region connected to the base region, an emitter electrode, a base electrode, and at lease one of first and second resistive layers of granular metal-dielectric material. The first resistive layer is disposed between the emitter region and the emitter electrode, and the second resistive layer is disposed between the base region and the base electrode.

In still another aspect of the present invention, a semiconductor structure for fabricating bipolar transistors is composed of a semiconductor substrate, an epitaxial semiconductor layer on the semiconductor substrate, and a resistive layer of granular metal-granular material, disposed to cover the epitaxial semiconductor layer. The resistive layer preferably includes a dielectric matrix having a relative dielectric constant equal to or more than 10. In addition, a temperature coefficient of resistivity of the resistive layer is preferably positive.

The epitaxial semiconductor layer may include a first semiconductor film of a first conductivity type on the semiconductor substrate, a second semiconductor film of a second conductivity type on the first semiconductor film, and a third semiconductor film of the first conductivity type. A band gap of the third semiconductor film is larger than that of the second semiconductor film.

The semiconductor preferably includes an electrode layer of metal or alloy disposed between the epitaxial semiconductor layer and the resistive layer, the electrode layer and the resistive layer forming a ohmic contact.

In yet still another aspect of the present invention, a method of fabricating a bipolar transistor comprising:
forming a collector region;
forming a base region connected to the collector region;
forming an emitter region connected to the base region;
forming an emitter electrode;
forming a base electrode; and
forming at lease one of first and second resistive layers of granular metal-dielectric material, the first resistive layer being disposed between the emitter region and the emitter electrode, and the second resistive layer being disposed between the base region and the base electrode.

### BRIEF DESCRIPTION OF DRAWINGS

FIG. 1 is a cross-sectional view of a bipolar transistor in a first embodiment of the present invention;

FIGS. 2 to 8 are cross-sectional views illustrating a fabrication process of the bipolar transistor in the first embodiment;

FIG. 9 is a plan view of a multi-finger HBT into which the bipolar transistors in the first embodiment are integrated;

FIG. 10 is a cross-sectional view of a bipolar transistor in a second embodiment of the present invention;

FIGS. 11 to FIG. 15 are cross-sectional views illustrating a fabrication process of the bipolar transistor in the second embodiment of the present invention; and

FIG. 16 is a cross-sectional view of a modification of the bipolar transistors in first and second embodiment.

### BEST MODE FOR CARRYING OUT THE INVENTION

Preferred embodiments of the present invention are described below in detail with reference to the attached drawings.

### First Embodiment

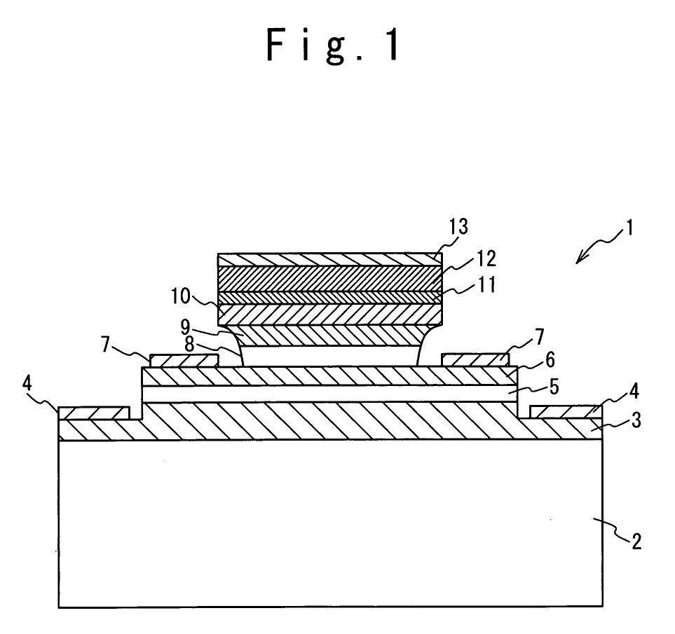

In a first embodiment of the present invention, as shown in FIG. 1, an NPN-type heterobipolar transistor 1 is formed on an intrinsic GaAs substrate 2. The heterobipolar transistor 1 includes an emitter whose band gap is larger than that of a base.

A collector contact layer 3 is disposed on the substrate 2. The collector contact layer 3 is formed of a heavily doped n-type GaAs film. A portion of the collector contact layer 3 is covered with a collector electrode 4 including a series of conductive layers: a AuGe layer, an Ni layer, and a Au layer (not shown). The collector electrode 4 is in contact with the collector contact layer 3 on the AuGe layer to form an ohmic contact between the collector contact layer 3 and the collector electrode 4.

A collector layer 5 is disposed on the collector contact layer 3. The collector layer 5 is composed of an n-type GaAs film.

A base layer 6 is disposed on the collector layer 5. The base layer 6 is composed of a heavily doped p-type GaAs film. A portion of the base layer 6 is covered with a base electrode 7 including a series of metal layers: a Pt layer, a Ti layer and a Au layer (not shown). The base electrode 7 is in contact with the base layer 6 on the Pt layer to form an ohmic contact between the base layer 6 and the base electrode 7.

An emitter layer 8 is disposed on the base layer 6. The emitter layer 8 is composed of an n-type InGaP film. The band gap of the emitter layer 8 is larger that that of the base layer 6, which is composed of the heavily doped p-type GaAs film.

First and second emitter contact layers 9, and 10 are disposed in series to cover the emitter layer 8. The first emitter contact layer 9 is composed of a heavily doped n-type GaAs film, and the second emitter contact layer 10 is composed of a heavily doped n-type InGaAs film.

An ohmic electrode layer 11 is disposed on the second emitter contact layer 10. The ohmic electrode layer 11 includes a series of metal or alloy layers: a AuGe layer, a Ni layer and a Au layer (not shown). The ohmic electrode layer 11 is in contact with the second emitter contact layer 10 on the AuGe layer, and the Au layer is positioned on the top of the ohmic electrode layer 11. The structure thus described allows the contact between the second emitter contact layer 10 and the ohmic electrode 11 to be ohmic.

A resistive layer 12 is disposed on the ohmic electrode 11, and an emitter electrode 13, such as a Au layer, is disposed on the resistive layer 12.

The resistive layer 12 functions as a ballast resistor, and has a sufficiently large perpendicular resistance to avoid thermal runaway of the bipolar transistor 1. In one embodiment, the perpendicular resistance of the resistive layer 12 ranges from 10 to 30 ohm.

In order to increase the perpendicular resistance of the resistive layer 12 with its thickness reduced, the resistive layer 12 is formed of granular metal-dielectric composite which includes an dielectric matrix, and metal granules distributed into the dielectric matrix. Granular metal-dielectric composite exhibits both metallic and dielectric characteristics, ant thus the resistivity of granular metal-dielectric composite is easily and widely adjustable by a volume ratio of the metal granules and the dielectric matrix. The use of granular metal-dielectric composite advantageously provides the sufficiently large resistance for the resistive layer 12 to avoid thermal runaway. The dielectric matrix of the resistive layer 12 may be formed of silicon oxide. The metal granules may be formed of metal insoluble to the dielectric matrix, such as palladium, nickel, platinum, gold, aluminum, iron, copper, silver, and tungsten.

The granular metal-dielectric composite of the resistive layer 12 preferably has a positive thermal coefficient of the resistivity. In other words, the resistive layer 12 is preferably formed of granular metal-dielectric composite whose resistivity increases as increasing temperature and decreases as decreasing temperature.

The positive thermal coefficient of the resistive layer 12 enables an automatic control of the resistivity of the resistive layer 12 to a desired value. In the event that the junction temperature of the bipolar transistor 1 is relatively low, increasing the gain of the transistor 1 is more important than avoiding thermal runaway, while avoiding thermal runaway is critical in the event that the junction temperature is relatively high. The positive thermal coefficient of the resistive layer 12 achieves preferable control of thermal coefficient of the resistive layer 12. Decrease in the junction temperature reduces the resistivity of the resistive layer 12 because of the positive thermal coefficient thereof, and thus automatically increases the gain of the bipolar transistor. On the other hand, increase in the junction temperature increases the resistivity of the resistive layer 12 thus effectively avoids thermal runaway of the bipolar transistor 1.

The dielectric matrix of the resistive layer 12 is preferably formed of high k material having a relative dielectric constant more than 10, more preferably more than 100. The dielectric matrix having a large dielectric constant allows the resistive layer 12 to function as not only a ballast resistor but also a bypass capacitor, which effectively reduces the impedance of the resistive layer 12 in high frequencies. The dielectric matrix of the resistive layer 12 is preferably formed of tantalum oxide (Ta₂O₅), and hafnium oxide (HfO₂). More preferably, the dielectric matrix is formed of perovskite oxides, such as TiO₂, BaTiO₃, SrTiO₃, BaSrTiO₃, PbTiO₃, PbLaTiO₃, PbZrTiO₃, and PbLaZrTiO₃.

An exemplary relative dielectric constant of the dielectric matrix of the resistive layer 12 is given as follows. The perpendicular resistance of the resistive layer 12, that is, the resistance R of the ballast resistor is given by the following formula:
R=dρ/S, (1)
where d, S, and ρ are the thickness, the area, and resistivity of the resistive layer 12, respectively. The capacitance between the ohmic electrode 11 and the emitter electrode 13, that is, the capacitance C of the bypass capacitor is given by the following formula:
C=ε₀εᵣS/d, (2)
where ε₀ is the dielectric constant of the vacuum, εᵣ is the relative dielectric constant of the resistive layer 12. When an RF signal outputted from the bipolar transistor 1 ranges around a RF signal frequency f, the impedance of the bypass capacitor at the frequency f must be negligibly small compared to that of the ballast resistor.
Therefore, it holds:
2πfRC>>1, or
2πε₀εᵣfρ>>1. (3)
The following formula is obtained from the formula (3):
εᵣfρ>>1.8×10¹⁰.(Ωm/s)
When the RF signal frequency f is 10 (GHz), and the resistivity ρ is 10⁻² (Ωm), the relative dielectric constant εᵣ of the dielectric matrix is required to satisfy the following equation:
εᵣ>>180. (4)
The use of barium titanate (BaTiO₃) as the dielectric matrix allows the resistive layer 12 to satisfy the formula (4). When the RF signal frequency ranges in the EHF region, the dielectric matrix may be formed of other perovskite oxides, such as, TiO₂ and SrTiO₃.

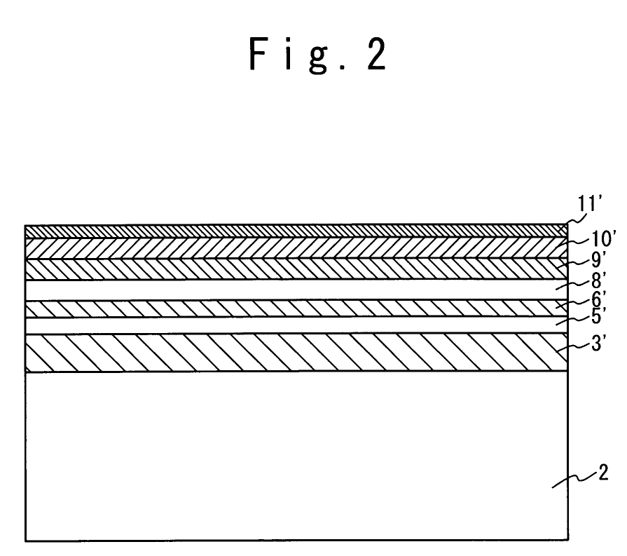

FIGS. 2 to 6 shows an exemplary fabrication process of the bipolar transistor 1. As shown in FIG. 2, the fabrication process begins with depositing, on the GaAs substrate 2, a series of semiconductor films: an n⁺-GaAs film 3′, an n-GaAs film 5′, an p⁺-GaAs film 6′, an n-InGaP film 8′, an n⁺-GaAs film 9′, and an n⁺-InGaAs film 10′. The deposition of these semiconductor films are achieved by an epitaxial growth technique. The n⁺-InGaAs film 10′ is then covered with a series of conductor films: a AuGe film, a Ni film, and a Au film to form a layered metal film 11′. As described later, the ohmic electrode layer 11 is obtained by etching the layered metal film 11′.

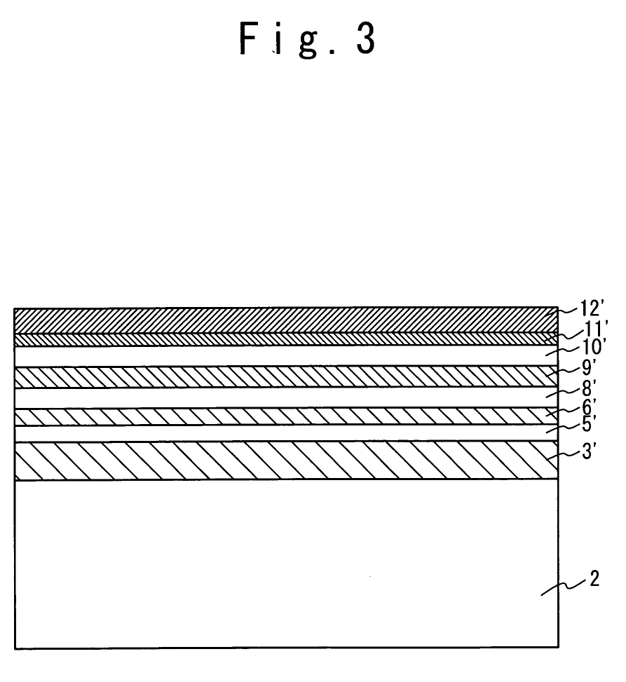

After the deposition of the layered metal film 11′, as shown in FIG. 3, a granular metal-dielectric film 12′ is formed on the layered metal film 11′. The granular metal-dielectric film 12′ consists of an dielectric matrix and metal granules distributed into the dielectric matrix. As described later, the resistive layer 12 is obtained by etching the granular metal-dielectric film 12′. An exemplary thickness of the granular metal-dielectric film 12′ is 100 nm.

The deposition of the granular metal-dielectric film 12′ is preferably achieved by an ion beam sputtering technique. Exemplary deposition conditions of the granular metal-dielectric film 12′ are as follows: a sputter target is composed of a sintered insulator compact with a metal block disposed thereon. The sputter target may be a sintered compact of composite of metal and insulator. The acceleration voltage of the ion beam used to sputter the target is 1 kV, the ion current density is 0.5 mA/cm², and the ion current is about 6 to 7 mA. The pressure of the chamber in which the granular metal-dielectric film 12′ is deposited is regulated to about 5×10⁻⁵ Torr, and the neutralizer current is regulated to 9 to 10 mA to be 1.2 to 1.3 times as large as the ion current. The GaAs substrate 2 is not heated during the deposition of the granular metal-dielectric film 12′.

One skilled in the art would appreciate that the granular metal-dielectric film 12′ may be deposited by using other techniques. It should be noted, however, that the use of the ion beam sputtering is preferable to reduce the damage of the series of the semiconductor layers of the bipolar transistor 1.

The semiconductor structure shown in FIG. 3 may be commercially distributed as a partly finished product.

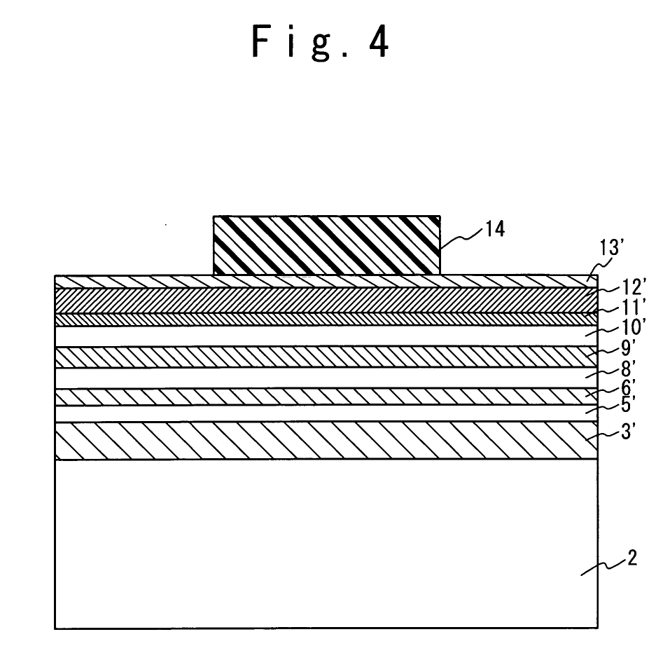

After a deposition of a Au film 13′ on the granular metal-dielectric film 12′, as shown in FIG. 4, a photoresist layer 14 is deposited on the Au film 13′. The deposition of the photoresist layer 14 is achieved by a photolithography technique, which is common in the art. As described later, the emitter electrode 13 is formed by etching the Au film 13′.

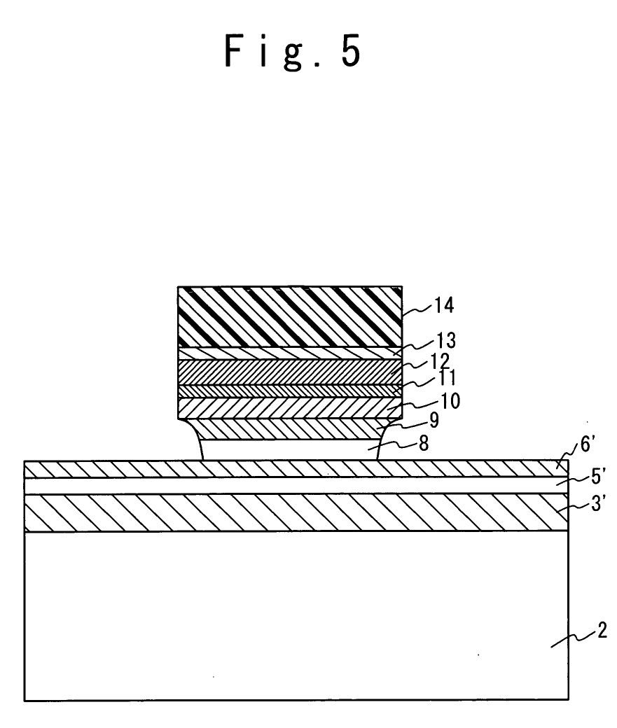

As shown in FIG. 5, the Au film 13′, the granular metal-dielectric film 12′, the layered metal film 11′, the n⁺-InGaAs film 10′, the n⁺-GaAs film 9′, and the n-InGaP film 8′ are then sequentially etched with the photoresist layer 14 used as a mask to form the emitter electrode 13, the resistive layer 12, the ohmic electrode layer 11, the second emitter contact layer 10, the first emitter contact layer 9, and the emitter layer 8, respectively. The etching of the n⁺-GaAs film 9′ and the n-InGaP film 8′ is executed under the conditions that side etch of the n⁺-GaAs film 9′ and the n-InGaP film 8′ progresses to some extend and side etch of the n⁺-InGaAs film 10′ is substantially completely suppressed. The etching conditions thus described forms overhangs on the sides of the emitter layer 8, and the first emitter contact layer 9.

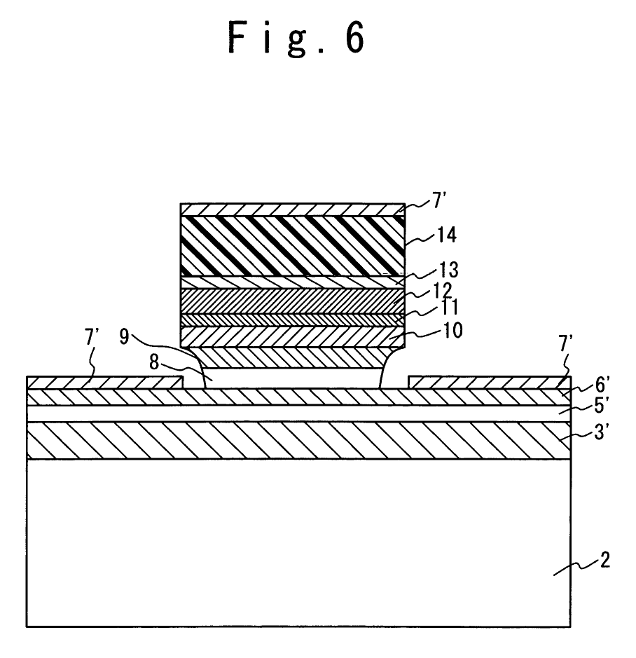

A shown in FIG. 6, a series of films including a Pt film, a Ti film, and a Au film are then sequentially deposited to form a layered metal film 7′ covering the entire structure. The overhangs on the sides of the emitter layer 8, and the first emitter contact layer 9 separates the layered metal film 7′ into two portions, one of which being formed on the photoresist layer 14, and the other being formed on the p⁺-GaAs film 6′.

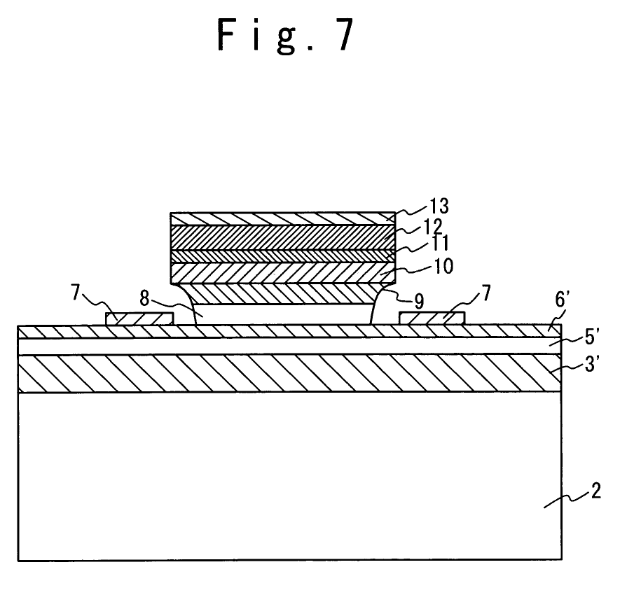

After the photoresist layer 14 and the portion of the layered metal film 7′ on the photoresist layer 14 are stripped off by a lift-off technique, as shown in FIG. 7, the remaining portion of the layered metal film 7′ is etched to form the base electrode 7. The etching of the layered metal film 7′ exposes a portion of the p⁺-GaAs film 6′.

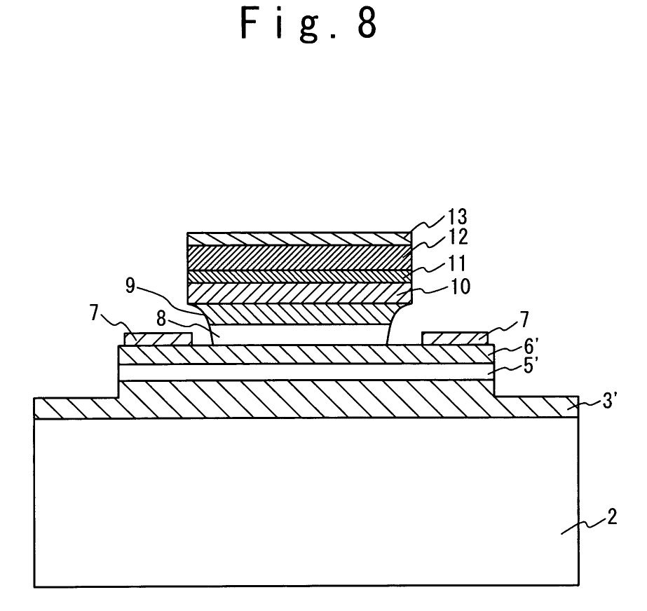

As shown in FIG. 8, the p⁺-GaAs film 6′, the n-GaAs film 5′, and the surface portion of the n⁺-GaAs film 3′ are then etched to form the base layer 6, the collector layer 5 and the collector contact layer 3. The remaining portion of the collector contact layer 3 is partially exposed by this etching. The collector electrode 4 is then formed on the exposed portion of the collector contact layer 3. The formation of the collector electrode 4 completes the bipolar transistor 1 shown in FIG. 1.

As thus described, the use of the granular metal-dielectric composite (or material) provides the resistive layer 12 with a sufficiently large perpendicular resistance without unacceptably increasing the thickness of the resistive layer. This enables the integration of a ballast resistor within the bipolar transistor, which is commercially acceptable from the viewpoint of both resistance and thickness.

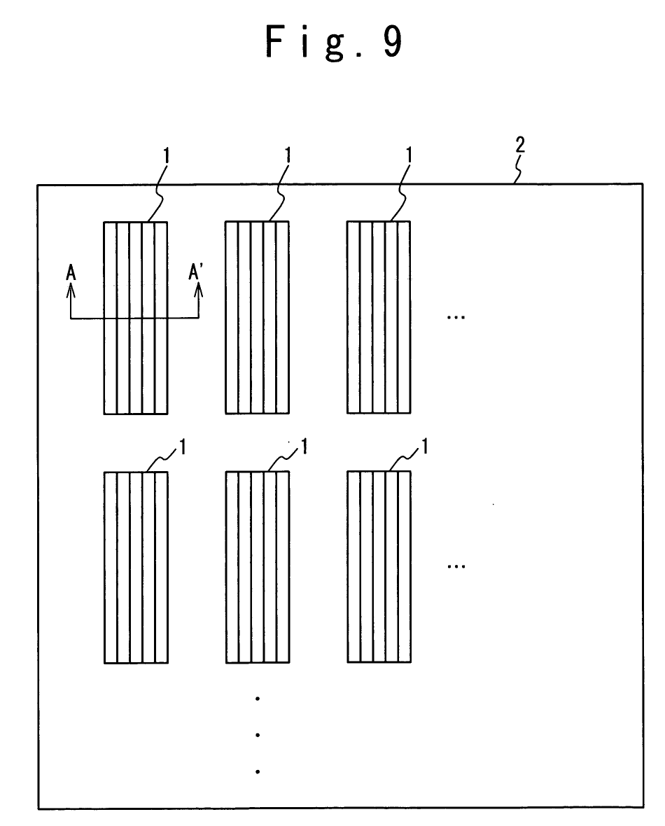

The bipolar transistor 1 in this embodiment is suitable for a multi-finger HBT. Preferably, as shown in FIG. 9, a plurality of the bipolar transistors 1 are arranged in rows and columns to form a multi-finger HBT. The multi-finger HBT has the collector electrodes 4 connected to each other by collector interconnections (not shown), the base electrodes 7 connected to each other by base interconnections (not shown), and the emitter electrodes 13 connected to each other by emitter interconnections (not shown).

In the event that the multi-finger HBT is composed of the array of the bipolar transistors 1, the positive thermal coefficient of the resistivity of the resistive layer 12 is especially preferable, because the positive thermal coefficient enables an automatic control of the resistance of the resistive layer 12 of the each bipolar transistor 1 comprised in the multi-finger HBT. The junction temperatures of the bipolar transistors 1 depend on the positions of the bipolar transistors. The junction temperature of the bipolar transistors 1 in the middle of the transistor array, for example, is higher than that on the circumference of the transistor array. The positive thermal coefficient of the resistivity of the resistive layers 12 decreases the resistance of the resistive layers 12 on the circumference of the array to improve RF characteristics of the associated bipolar transistors 1, while increasing the resistance of the resistive layers 12 at the center of the array to avoid thermal runaway of the associated bipolar transistors 1.

In an alternative embodiment, the ohmic electrode layer 11 may be removed from the bipolar transistor 1, and the resistive layer 12 may be directly contacted with the second emitter contact layer 10. It should be noted, however, that the direct contact of the resistive layer 12 and the second emitter contact layer 10 undesirably forms a Schottky contact therebetween, and thus increases the contact resistance. It is advantageous that the ohmic electrode layer 11 is disposed to form a ohmic contact between the resistive layer 12 and the second emitter contact layer 10.

### Second Embodiment

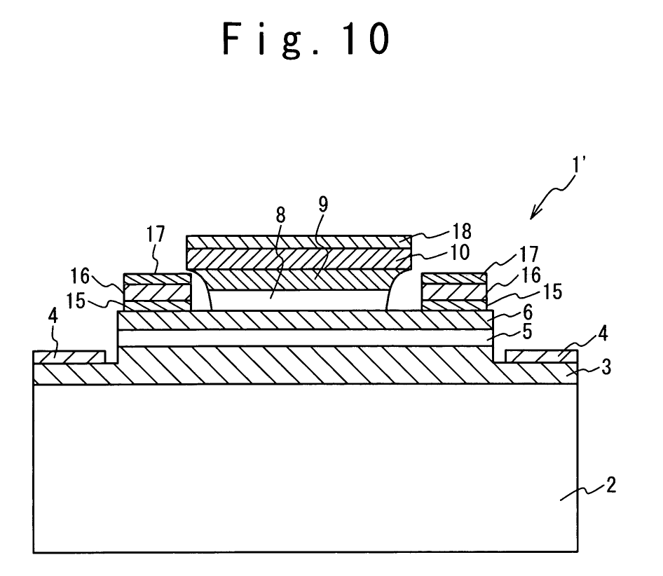

FIG. 10 shows an NPN bipolar transistor 1′ in a second embodiment. The bipolar transistor 1′ is similar to the bipolar transistor 1 described in the first embodiment, except for that the bipolar transistor 1′ includes an ohmic electrode layer 15, a resistive layer 16, and a base electrode 17 in place of the base electrode 7, and includes an emitter electrode 18 in place of the ohmic electrode layer 11, the resistive layer 12, and the emitter electrode 14. In the second embodiment, thermal runaway of the bipolar transistor 1′ is avoided by the resistive layer 16 disposed between the base layer 6 and the base electrode 17.

The emitter electrode 18, which is disposed on the second emitter contact layer 10, is composed of a series of metal layers including a AuGe layer, a Ni layer, and a Au layer (not shown). The emitter electrode 18 is in contact with the second emitter contact layer 10 on the AuGe layer to form an ohmic contact between the second emitter contact layer 10 and the emitter electrode 18.

The ohmic electrode layer 15, which is disposed on the base layer 6, is composed of a series of metal layers including a Pt layer, a Ti layer, and a Au layer (not shown). The ohmic electrode layer 15 is in contact with the base layer 6 on the Pt layer to form an ohmic contact between the ohmic electrode layer 15 and the base layer 6.

The base electrode 17, which is disposed on the resistive layer 16, is composed of a Au layer.

The resistive layer 16, disposed between the ohmic electrode layer 15 and the base electrode 17, is required to have a perpendicular resistance sufficient to avoid thermal runaway of the bipolar transistor 1′. In order to provide a sufficient perpendicular resistance for the resistive layer 16 along with a reduced thickness, the resistive layer 16 is formed of granular metal-dielectric composite. As described in the first embodiment, the resistive layer 16 is preferably composed of a granular metal-dielectric composite having a positive thermal coefficient of the resistivity. This enables an automatic control of the resistive layer 16, which functions as a ballast resistor, to a desired value.

As is the case with the resistive layer 12 in the first embodiment, the dielectric matrix of the resistive layer 16 is preferably formed of dielectric material having a relative dielectric constant more than 10. The dielectric matrix having a large dielectric constant allows the resistive layer 16 to function as not only a ballast resistor but also a bypass capacitor which effectively reduces the impedance of the resistive layer 16 in high frequencies.

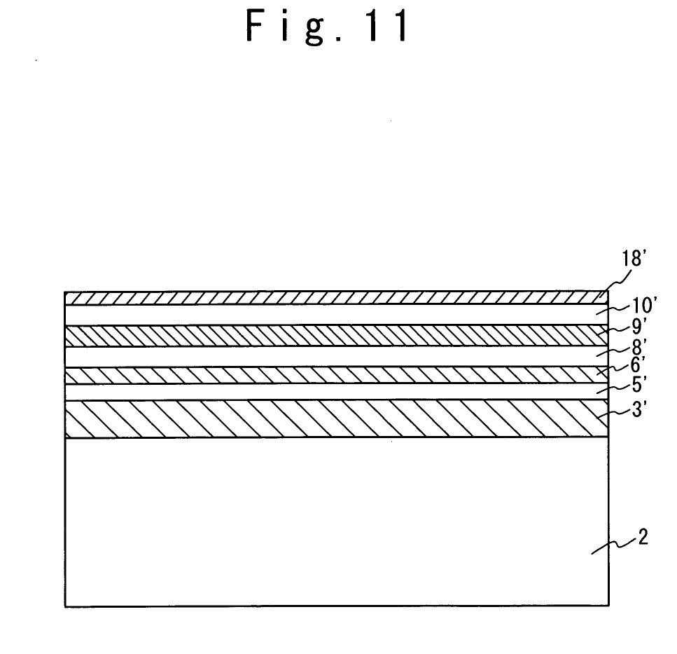

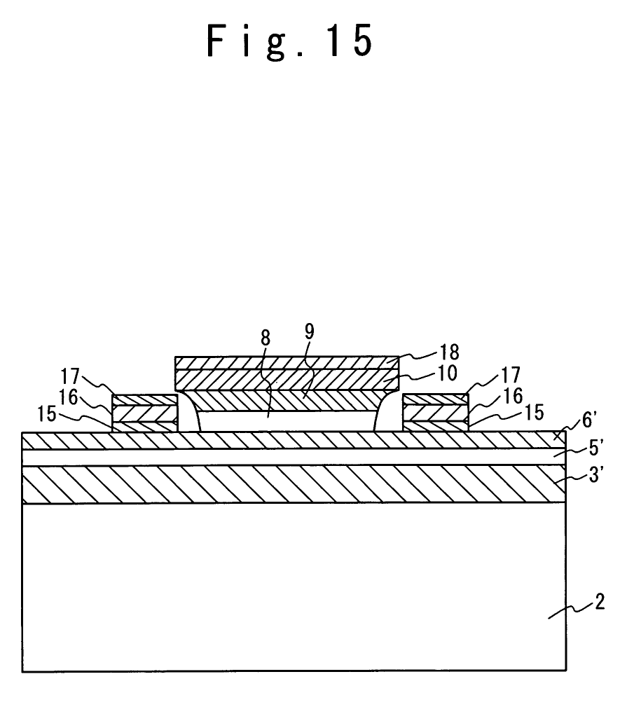

FIGS. 11 to 15 shows an exemplary fabrication process of the bipolar transistor 1′ in the second embodiment. As shown in FIG. 11, the fabrication process begins with depositing, on the GaAs substrate 2, a series of semiconductor films: an n⁺-GaAs film 3′, an n-GaAs film 5′, an p⁺-GaAs film 6′, an n-InGaP film 8′, an n⁺-GaAs film 9′, and an n⁺-InGaAs film 10′. The deposition of these semiconductor films are achieved by an epitaxial growth technique. A AuGe film, an Ni film, and a Au film are then deposited in series to form a layered metal film 18′ on the n⁺-InGaAs film 10′.

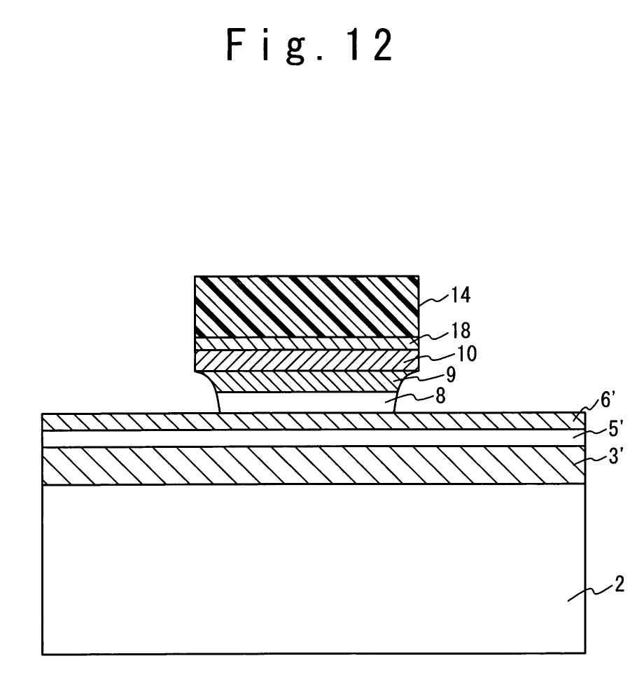

After forming a photoresist layer 14 on the layered metal film 18′, as shown in FIG. 12, the layered metal film 18′, the n⁺-InGaAs film 10′, n⁺-GaAs film 9′, and the n-InGaP film 8′ are sequentially etched with the photoresist layer 14 used as a mask to form the emitter electrode 18, the second emitter contact layer 10, the first emitter contact layer 9, and the emitter layer 8.

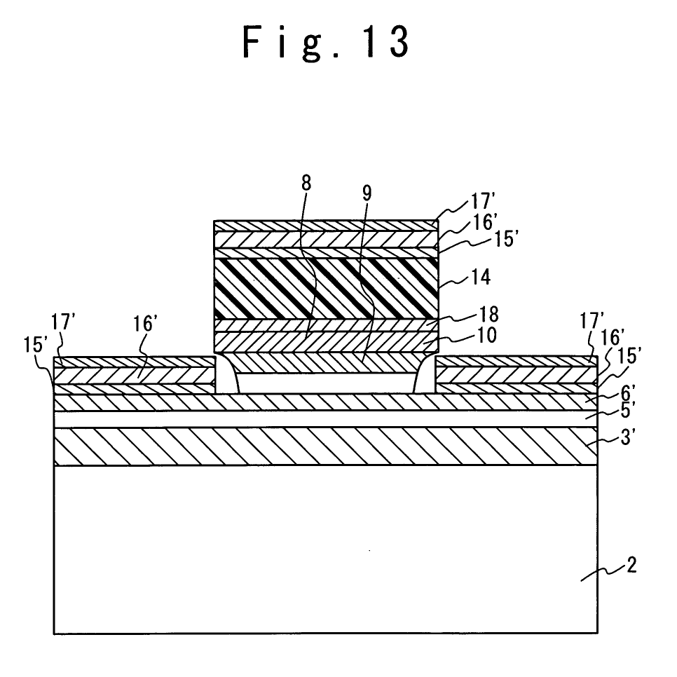

As shown in FIG. 13, a layered metal film 15′, a granular metal-dielectric film 16′, and a Au film 17′ are then deposited in series to cover the entire structure. The layered metal film 15′ consists of a series of metal films: a Pt film, a Ti film, and a Au film. The granular metal-dielectric film 16′ consists of a dielectric matrix and metal granules distributed into the dielectric matrix. The deposition conditions of the granular metal-dielectric film 16′ are the same as those of the granular metal-dielectric film 12′ described in the first embodiment.

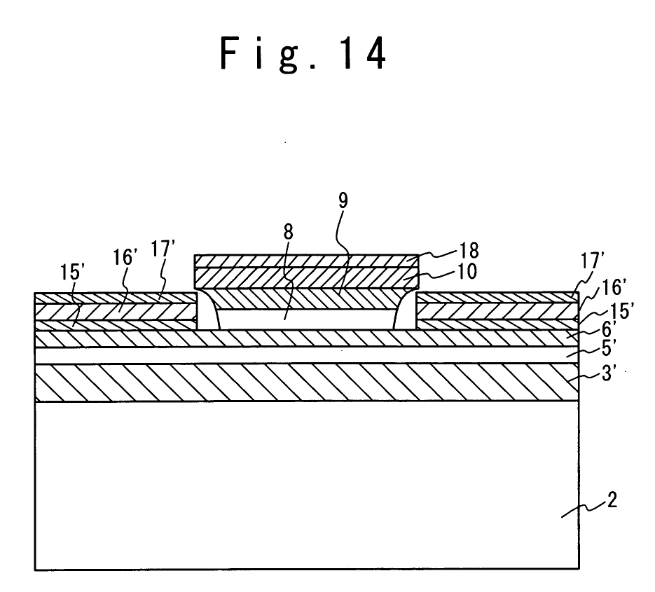

As shown in FIG. 14, the photoresist layer 14 and portions of the layered metal film 15′, the granular metal-dielectric film 16′, and the Au film 17′ disposed on the photoresist layer 14 are then stripped off by a lift off technique.

After the lift-off, remaining portions of the layered metal film 15′, the granular metal-dielectric film 16′, and the Au film 17′ are then partially etched to expose the p⁺-GaAs film 6′. This etching completes the ohmic electrode layer 15, the resistive layer 16, and the base electrode 16.

The p⁺-GaAs film 6′, the n-GaAs film 5′ and the n⁺-GaAs film 3′ are then partially etched to form the base layer 6, the collector layer 5, and the collector contact layer 3. A portion of the collector contact layer 3 is exposed by this etching. A collector electrode 4 is then formed on the exposed portion of the collector contact layer 3 to complete the bipolar transistor 1′ shown in FIG. 10.

As thus described, the use of the granular metal-dielectric composite (or material) provides the resistive layer 16 with a sufficiently large perpendicular resistance without unacceptably increasing the thickness of the resistive layer 16. This enables the integration of a ballast resistor within the bipolar transistor, which is commercially acceptable from the viewpoint of both resistance and thickness.

The bipolar transistor 1′ in this embodiment is also suitable for a multi-finger HBT. Preferably, a plurality of the bipolar transistors 1′ are arranged in rows and columns to form a multi-finger HBT. The multi-finger HBT has the collector electrodes 4 connected to each other by collector interconnections (not shown), the base electrodes 17 connected to each other by base interconnections (not shown), and the emitter electrodes 18 connected to each other by emitter interconnections (not shown).

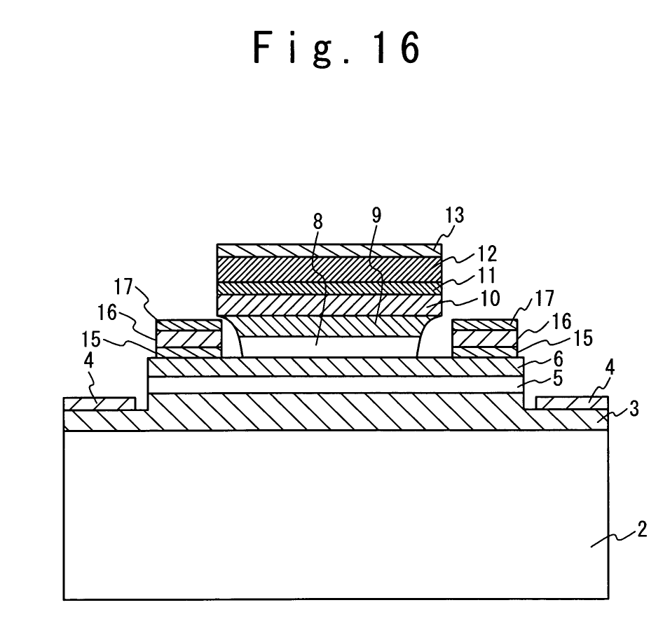

In an alternative embodiment, as shown in FIG. 16, the bipolar transistor includes a stack of the ohmic electrode layer 11, the resistive layer 12, and the emitter electrode 13 on the second emitter contact layer 10, which are described in the first embodiment, as well as the ohmic electrode layer 15, the resistive layer 16, and the base electrode 17. In this embodiment, the fabrication process includes depositing the layered metal film 11′, the granular metal-dielectric film 12′, and the Au film 13′ in place of depositing the Au film 18′. After the deposition, the layered metal film 11′, the granular metal-dielectric film 12′, and the Au film 13′ are then etched with the photoresist layer 14 used as a mask to form the ohmic electrode layer 11, the resistive layer 12, and the emitter electrode 13.

In another alternative embodiment, the ohmic electrode layer 15 may be removed from the bipolar transistor 1 and the resistive layer 16 may be directly contacted with the base layer 6. It should be noted, however, that the direct contact of the resistive layer 16 and the base layer 6 undesirably forms a Schottky contact therebetween, and thus increases the contact resistance. It is advantageous that the ohmic electrode layer 15 is disposed to form a ohmic contact between the resistive layer 16 and base layer 6.

1. A bipolar transistor comprising:
a collector region;
a base region connected to said collector region;
an emitter region connected to said base region;
an emitter electrode;
a base electrode; and
at lease one of first and second resistive layers of granular metal-dielectric composite, wherein said first resistive layer is disposed between said emitter region and said emitter electrode, and said second resistive layer is disposed between said base region and said base electrode.

2. The bipolar transistor according to claim 1, further comprising an electrode film disposed between said first resistive layer and said emitter region, wherein said electrode film and said resistive layer form an ohmic contact.

3. The bipolar transistor according to claim 1, further comprising an electrode film disposed between said second resistive layer and said base region, wherein said electrode film and said resistive layer form an ohmic contact.

4. The bipolar transistor according to claim 1, wherein
said resistive layer includes:
a dielectric matrix;
metal granules distributed in said dielectric matrix, wherein said dielectric matrix has a relative dielectric constant equal to or more than 10.

5. The bipolar transistor according to claim 1, wherein said resistive layer has a perpendicular resistance sufficient to avoid thermal runaway of said bipolar transistor.

6. The bipolar transistor according to claim 1, wherein a temperature coefficient of resistivity of said resistive layer is positive.

7. The bipolar transistor according to claim 1, wherein a band gap of said emitter region is larger than that of said base regions.

8. A multi-finger bipolar transistor comprising:
a plurality of bipolar transistors fabricated within a substrate, wherein each of said plurality of bipolar transistors includes:
a collector region;
a base region connected to said collector region;
an emitter region connected to said base region;
an emitter electrode;
a base electrode; and
at lease one of first and second resistive layers of granular metal-dielectric composite, said first resistive layer being disposed between said emitter region and said emitter electrode, and said second resistive layer being disposed between said base region and said base electrode.

9. The multi-finger bipolar transistor according to claim 8, wherein said resistive layer comprises:
a dielectric matrix; and
metal granules distributed in said dielectric matrix, wherein said dielectric matrix has a relative dielectric constant equal to or more than 10.

10. The multi-finger bipolar transistor according to claim 8, wherein a temperature coefficient of resistivity of said resistive layer is positive.

11. The multi-finger bipolar transistor according to claim 8, wherein a band gap of said emitter region is larger than that of said base regions.

12. A semiconductor structure for fabricating bipolar transistors comprising:
a semiconductor substrate;
an epitaxial semiconductor layer on said semiconductor substrate; and
a resistive layer of granular metal-granular material, disposed to cover said epitaxial semiconductor layer.

13. The semiconductor structure according to claim 12, wherein said resistive layer comprises:
a dielectric matrix; and
metal granules distributed in said dielectric matrix, wherein said dielectric matrix has a relative dielectric constant equal to or more than 10.

14. The semiconductor structure according to claim 12, wherein a temperature coefficient of resistivity of said resistive layer is positive.

15. The semiconductor structure according to claim 14, wherein said epitaxial semiconductor layer includes:
a first semiconductor film of a first conductivity type on said semiconductor substrate,
a second semiconductor film of a second conductivity type on said first semiconductor film, and
a third semiconductor film of said first conductivity type, wherein a band gap of said third semiconductor film is larger than that of said second semiconductor film.

16. The semiconductor structure according to claim 12, further comprising an electrode layer of metal or alloy disposed between said epitaxial semiconductor layer and said resistive layer, wherein said electrode layer and said resistive layer form a ohmic contact.

17. A method of fabricating a bipolar transistor comprising:
forming a collector region;
forming a base region connected to said collector region;
forming an emitter region connected to said base region;
forming an emitter electrode;
forming a base electrode; and
forming at lease one of first and second resistive layers of granular metal-dielectric composite, wherein said first resistive layer is disposed between said emitter region and said emitter electrode, and said second resistive layer is disposed between said base region and said base electrode.
